(19) United States
(12) Patent Application Publication
(10) Pub. No.: US 2024/0371772 A1
(43) Pub. Date: Nov. 7, 2024

(54) VERTICAL POWER SEMICONDUCTOR DEVICE HAVING AN INTERLAYER DIELECTRIC STRUCTURE

(71) Applicant: Infineon Technologies AG, Neubiberg (DE)

(72) Inventors: Saurabh Roy, Villach (AT); Josef Schätz, Regensburg (DE); Dethard Peters, Hochstadt (DE); Hans-Joachim Schulze, Taufkirchen (DE)

(21) Appl. No.: 18/640,821

(22) Filed: Apr. 19, 2024

(30) Foreign Application Priority Data
May 4, 2023 (DE) 102023111590.1

(51) Int. Cl. H01L 23/532; H01L 29/16; H01L 29/66; H01L 29/78

(52) U.S. Cl. CPC H01L 23/5329; H01L 29/1608; H01L 29/66734; H01L 29/7803; H01L 29/7825

(57) ABSTRACT

A vertical power semiconductor device is proposed. The vertical power semiconductor device includes a silicon carbide (SIC) semiconductor body including a trench structure. The trench structure extends into the SiC semiconductor body at a first surface of the SiC semiconductor body. The trench structure includes a gate electrode and a gate dielectric arranged between the gate electrode and the SiC semiconductor body. An interlayer dielectric structure is arranged on the trench structure. The interlayer dielectric structure includes at least one of an aluminum nitride layer, a silicon nitride layer, an aluminum oxide layer, or a boron nitride layer. The vertical power semiconductor device further includes a source or emitter electrode on the interlayer dielectric structure.

### TECHNICAL FIELD

The present disclosure is related to a vertical power semiconductor device, in particular to a vertical power semiconductor device comprising an interlayer dielectric structure.

### BACKGROUND

Technology development of new generations of vertical power semiconductor devices, e.g. metal oxide semiconductor field effect transistors (MOSFETs), or insulated gate bipolar transistors (IGBTs), or junction field effect transistors (JFETs), aims at improving electric device characteristics and reducing costs by shrinking device geometries. Although costs may be reduced by shrinking device geometries, a variety of tradeoffs and challenges have to be met. Complying with reliability requirements requires design optimization when increasing device functionalities per unit area. For example, as the switching elements, e.g. MOSFETs, in power electronic systems can experience high temperature transients during short-circuit events or over-voltages caused by unclamped inductive switching, generated heat is required to be effectively dissipated. Under such operation conditions, the temperature of the power devices may reach high levels which may cause damage to the gate oxide of SiC power transistors. Moreover, such operation conditions may be accompanied by hot-spot formation. Thus, effective heat-dissipation is required for preventing device failure and for enhancing the reliability of new generations of vertical power semiconductor devices.

Thus, there is a need for an improved vertical power semiconductor device.

### SUMMARY

An example of the present disclosure relates to a vertical power semiconductor device. The vertical power semiconductor device comprises a silicon carbide (SIC) semiconductor body including a trench structure. The trench structure extends into the SiC semiconductor body at a first surface of the SiC semiconductor body. The trench structure includes a gate electrode and a gate dielectric arranged between the gate electrode and the SiC semiconductor body. An interlayer dielectric structure is arranged on the trench structure. The interlayer dielectric structure includes at least one of an aluminum nitride layer, a silicon nitride layer, an aluminum oxide layer, or a boron nitride layer. The vertical power semiconductor device further includes a source or emitter electrode on the interlayer dielectric structure.

Another example of the present disclosure relates to a method of manufacturing a vertical power semiconductor device. The method includes forming a trench structure into a silicon carbide (SiC) semiconductor body at a first surface of the SiC semiconductor body. The trench structure includes a gate electrode and a gate dielectric arranged between the gate electrode and the SiC semiconductor body. The method further includes forming an interlayer dielectric structure on the trench structure. The interlayer dielectric structure includes at least one of an aluminum nitride layer, a silicon nitride layer, an aluminum oxide layer, or a boron nitride layer. Thereafter, a source or emitter electrode is formed on the interlayer dielectric structure.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of vertical power semiconductor devices and together with the description serve to explain principles of the examples. Further examples are described in the following detailed description and the claims.

FIGS. 1 to 4 are schematic cross-sectional views for illustrating configuration examples of vertical power semiconductor devices including an interlayer dielectric over or close to a trench structure including a gate electrode.

FIG. 5 is a schematic cross-sectional view for illustrating a configuration example of a transistor cell of a vertical power semiconductor device.

FIG. 6 is a schematic top view for illustrating a configuration example of a layout of a vertical power semiconductor device.

### DETAILED DESCRIPTION

In the following detailed description, reference is made to the accompanying drawings, which form a part hereof and in which are shown by way of illustration specific examples of vertical power semiconductor devices. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact may be a non-rectifying electrical junction.

Ranges given for physical dimensions include the boundary values. For example, a range for a parameter y from a to b reads as a≤ y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of the present disclosure relates to a vertical power semiconductor device. The vertical power semiconductor device comprises a silicon carbide (SiC) semiconductor body including a trench structure extending into the SiC semiconductor body at a first surface of the SiC semiconductor body. The trench structure may include a gate electrode and a gate dielectric arranged between the gate electrode and the SiC semiconductor body. The vertical power semiconductor device may further include an interlayer dielectric structure on the trench structure. The interlayer dielectric structure may include at least one of an aluminum nitride layer, a silicon nitride layer, an aluminum oxide layer, or a boron nitride layer. The vertical power semiconductor device may further include a source or emitter electrode on the interlayer dielectric structure.

The vertical power semiconductor device may be part of or may be at least one of: an integrated circuit, a discrete semiconductor device, or a semiconductor module, for example. The semiconductor device may be used in applications related to power transmission and distribution, automotive and transport, renewable energy, consumer electronics, and other industrial applications. The vertical power semiconductor device may be or a may include an insulated gate field effect transistor (IGFET) such as a metal oxide semiconductor field effect transistor (MOSFET), an insulated gate bipolar transistor (IGBT), or a junction field effect transistor (JFET), for example.

For example, the semiconductor body may comprise or may be an epitaxially deposited semiconductor material. Separately or in combination, the semiconductor body may comprise a growth substrate. For example, vertical power semiconductor device may be based on a semiconductor body from a crystalline SiC material. For example, the semiconductor material may be 2H-SiC (SiC of the 2H polytype), 6H-SIC, 3C-SiC or 15R-SiC. According to an example, the semiconductor material is silicon carbide of the 4H polytype (4H-SiC). The semiconductor body may consist of a semiconductor substrate or may include or consist of a semiconductor substrate having none, one or more than one SiC layers, e.g. epitaxially grown SiC layers, thereon. Apart from semiconductor bodies based on SiC, other semiconductor materials may be used, e.g. silicon, Si, or gallium nitride, GaN.

The vertical power semiconductor device may have a load current flow between the first surface and a second surface opposite to the first surface. The first surface may be a front surface or a top surface of the semiconductor body, and the second surface may be a back surface or a rear surface of the semiconductor body, for example. The semiconductor body may be attached to a lead frame via the second surface, for example. Over the first surface of the semiconductor body, interconnects may be arranged on a contact pad structure, e.g. the source or emitter electrode, of a wiring area for electrically connecting device elements in the semiconductor body to elements, e.g. other semiconductor devices, outside of the semiconductor device, for example.

The vertical power semiconductor device may be configured to conduct currents of more than 1A, or more than 10 A, or more than 30 A, or more than 50A, or more than 75 A, or even more than 100A. The vertical power semiconductor device may be further configured to block voltages between load terminals, e.g. between collector and emitter of an IGBT, or between drain and source of a MOSFET or JFET, in the range of several hundreds of up to several thousands of volts, e.g. 400 V, 650V, 1.2 kV, 1.7 kV, 3.3 kV, 4.5 kV, 5.5 kV, 6 kV, 6.5 kV, 10 kV. The blocking voltage may correspond to a voltage class specified in a datasheet of the power semiconductor device, for example.

The blocking voltage of the vertical power semiconductor device may be adjusted by an impurity or doping concentration and/or a vertical extension of a drift region (drift zone) in SiC semiconductor body. The drift zone may be part of the at least one SiC semiconductor layer and/or SiC substrate. A doping concentration of the drift zone may gradually or in steps increase or decrease with increasing distance to the first surface at least in portions of its vertical extension. According to other examples, the impurity concentration in the drift zone may be approximately uniform. A mean impurity concentration in the drift zone may be between 5×10¹² cm³ and 1×10¹⁷ cm³, for example in a range from 1×10¹⁵ cm³ to 2×10¹⁶ cm³. A vertical extent of the drift zone may depend on voltage blocking requirements, e.g. a specified voltage class, of the device. When operating the vertical power semiconductor device in voltage blocking mode, a space charge region may vertically extend partly or totally through the drift zone depending on the blocking voltage applied to the vertical power semiconductor device. When operating the vertical power semiconductor device at or close to the specified maximum blocking voltage, the space charge region may reach or penetrate into a buffer region that is configured to prevent the space charge region from further reaching to the second load electrode at the second surface. The buffer region may have a higher doping concentration than the drift zone. The vertical profile of doping concentration in the buffer may enable an improvement of avalanche robustness and short circuit withstand capability. This may allow for further improving reliability of the vertical power semiconductor device.

For realizing a desired current carrying capacity, the vertical power semiconductor device may be designed by a plurality of parallel-connected transistor cells in a transistor cell area. The parallel-connected transistor cells may, for example, be transistor cells formed in the shape of a strip or a strip segment. The transistor cells can also have any other shape, e.g. circular, elliptical, polygonal such as hexagonal or octahedral. The transistor cells may be arranged in the transistor cell area of the semiconductor body. The transistor cell area may be an active area where a source region of a FET or JFET at the first surface and a drain region of the FET or JFET are arranged opposite to one another along the vertical direction. Likewise, the transistor cell area may be an active area where an emitter region of an IGBT at the first surface and a collector region of the IGBT are arranged opposite to one another along the vertical direction. In the transistor cell area, a load current may enter or exit the semiconductor body of the FET, or JFET, or IGBT, e.g. via contact plugs on the first surface of the semiconductor body. For example, the transistor cell area may be defined by an area where source contact plugs or emitter contact plugs are placed over the first surface.

The trench structure may be stripe-shaped, for example. The trench structure may also have another layout or geometry in a plan view, e.g. hexagonal, square, circular, elliptic. Sidewalls of the trench gate structure may be non-tapered or slightly tapered, for example. In case of slightly tapered sidewalls of the trench structure, such as for example using the a-plane, a channel length may be slightly larger than the vertical extent of a channel region. The taper angle of the trench structure may be caused by process technology, e.g. aspect ratio of trench etch processes, and may also be used for maximizing the charge carrier mobility in the channel region which depends from the direction along which channel current flows. Another example for a tapered trench structure is a V-shaped trench structure comprising the gate electrode.

The gate electrode of the trench structure may include one or more conductive material(s), e.g. metal, e.g. Cu, Au, AlCu, Ag, or alloys thereof, metal compounds, e.g. TiN, highly doped semiconductor material such as highly doped polycrystalline silicon. The one or more conductive materials may form a layer stack, for example.

The gate dielectric of the trench structure may include one or more dielectric layers for electrically isolating the gate electrode from the surrounding SiC semiconductor body, for example. Exemplary materials for the one or more dielectric layers are, inter alia, oxides (e.g. silicate glass, deposited SiO₂, thermal SiO₂), nitrides (e.g., Si₃N₄), high-k dielectrics, low-k dielectrics, or any combination thereof.

The vertical power semiconductor device may further include an edge termination area that may include a termination structure. In a blocking mode or in a reverse biased mode of a FET, or JFET, or IGBT, the blocking voltage between the transistor cell area and a field-free region laterally drops across the termination structure in the edge termination area. The termination structure may have a higher or a slightly lower voltage blocking capability than the transistor cell area. The termination structure may include a junction termination extension (JTE) with or without a variation of lateral doping (VLD), one or more laterally separated guard rings, or any combination thereof, for example. The wiring area may laterally adjoin to a passivation area that may be arranged over the edge termination area of the vertical power semiconductor device, for example.

The source or emitter electrode may be part of a wiring area over the semiconductor body. The wiring area may include one or more than one, e.g. two, three, four or even more wiring levels. Each wiring level may be formed by a single one or a stack of conductive layers, e.g. metal layer(s). For example, the wiring levels may include at least one of Cu, Au, AlCu, Ag, or alloys thereof. The wiring levels may be lithographically patterned, for example. Between stacked wiring levels, a dielectric layer or layer structure may be arranged. Contact plug(s) or contact line(s) may be formed in openings in the dielectric layer or layer structure to electrically connect parts, e.g. metal lines or contact areas, of different wiring levels to one another. The source or emitter electrode may be formed by one or more elements of the wiring area over the first surface. For example, the source or emitter electrode may include a source or emitter pad that may be used as a bonding area. The source or emitter electrode may also include further conductive structures e.g. contact plugs or lines, between the transistor cell area at the first surface and a source or emitter pad of the source or emitter electrode, for example. Likewise, a drain or collector electrode may be formed by one or more elements of a wiring area over the second surface.

The interlayer dielectric on the trench structure may allow for an effective heat dissipation, thereby protecting the gate dielectric in the trench structure of the vertical power semiconductor device from damage due to overheat. This may allow for improving reliability of vertical power semiconductor devices.

For example, the interlayer dielectric structure may be predominantly formed by or consists of the at least one of the aluminum nitride layer, the silicon nitride layer, the aluminum oxide layer, or the boron nitride layer. Other dielectric materials, e.g. SiO₂ or dielectric materials having a higher thermal conductivity than SiO₂ may be used in combination with the at least one of the aluminum nitride layer, the silicon nitride layer, the aluminum oxide layer, or the boron nitride layer for forming the interlayer dielectric structure, for example.

For example, a bottom side of the interlayer dielectric structure may directly adjoin to each of the first surface of the SiC semiconductor body, the gate dielectric, and the gate electrode. For example, the interlayer dielectric structure may directly adjoin to an n⁺-doped source region at the first surface of the SiC semiconductor body. In some examples, the interlayer dielectric structure may directly adjoin to a p-doped body region and/or to a p⁺-doped body contact region, for example.

For example, the interlayer dielectric layer on the trench structure be arranged over or above the trench structure and/or close to the trench structure.

For example, a top side of the interlayer dielectric structure may directly adjoin to the source or emitter electrode, e.g. to a bottom side of the source or emitter electrode.

For example, the at least one of the aluminum nitride layer, the silicon nitride layer, the aluminum oxide layer, or the boron nitride layer may directly adjoin to the gate dielectric.

For example, the interlayer dielectric structure may further include a first dielectric layer between the at least one of the aluminum nitride layer, the silicon nitride layer, the aluminum oxide layer, or the boron nitride layer and the trench structure. For example, the first dielectric layer may be an oxide layer or a nitride layer.

For example, a ratio of a thickness of the at least one of the aluminum nitride layer, the silicon nitride layer, the aluminum oxide layer, or the boron nitride layer to a thickness of the first dielectric layer may range from 2 to 200, or from 5 to 100. For example, the at least one of the aluminum nitride layer, the silicon nitride layer, the aluminum oxide layer, or the boron nitride layer may have a thickness ranging from 100 nm to 1 μm, or from 300 nm to 900 nm. The first dielectric layer, e.g. an SiO₂ layer, may have a thickness ranging from 5 nm to 100 nm, or from 10 nm to 70 nm. This relation of thicknesses may allow for avoiding a negative effect, i.e. reduction, of the improvement of the thermal behavior caused by the at least one of the aluminum nitride layer, the silicon nitride layer, the aluminum oxide layer, or the boron nitride layer.

For example, the interlayer dielectric structure may further include a second dielectric layer between the source or emitter electrode and the at least one of the aluminum nitride layer, the silicon nitride layer, the aluminum oxide layer, or the boron nitride layer. For example, the second dielectric layer may be an oxide layer or a nitride layer.

For example, a ratio of a thickness of the at least one of the aluminum nitride layer, the silicon nitride layer, the aluminum oxide layer, or the boron nitride layer to a thickness of the second dielectric layer may range from 2 to 200, or from 5 to 100.

For example, a thickness of the at least one of the aluminum nitride layer, the silicon nitride layer, the aluminum oxide layer, or the boron nitride layer may range from 200 nm to 5 μm, or from 200 nm to 1 μm.

For example, the vertical power semiconductor device may further include a channel region adjoining to a first sidewall of the trench structure. Sidewalls of the trench gate structure may be non-tapered or slightly tapered, for example. The vertical power semiconductor device may further include a diode region adjoining to a second sidewall and to a bottom side of the trench structure. The second sidewall may be opposite to the first sidewall. The channel region may be part of a body region that adjoins to the first sidewall. A conductivity in the channel region may be adjusted by field effect via a gate voltage applied to the gate electrode, for example. The channel region may be an inversion channel in an on-state of the vertical power semiconductor device, for example. In some examples, the diode region may include at least two sub-regions along the vertical direction. A vertical doping concentration profile of each of the at least two sub-regions may have a doping concentration peak. For example, a doping concentration peak of one or more of the at least two sub-regions may be located at a larger vertical distance to a reference level at a first surface of the semiconductor body than a bottom side of the trench structure.

For example, the vertical power semiconductor device may further include a drain or collector electrode over a second surface of the SiC semiconductor body. The vertical power semiconductor device may further include a drift zone in the SiC semiconductor body between the source or emitter electrode and the drain or collector electrode. A doping concentration profile of the drift zone may be configured for a nominal blocking voltage between the drain or collector electrode and the source or emitter electrode in a range from 300 V to 20 kV, for example. The nominal blocking voltage may also be lower, e.g. ranging from 12 V to 40 V, or from 45 V to 80 V, or from 85 V to 300 V, for example.

Details with respect to structure, or function, or technical benefit of features described above with respect to a FET, or JFET, or IGBT likewise apply to the exemplary methods described herein. Processing the semiconductor body may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, e.g. by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

An example of the present disclosure relates to a method of manufacturing a vertical power semiconductor device. The method may include forming a trench structure into a silicon carbide (SiC) semiconductor body at a first surface of the SiC semiconductor body. Sidewalls of the trench gate structure may be non-tapered or slightly tapered, for example. The trench structure may include a gate electrode and a gate dielectric arranged between the gate electrode and the SiC semiconductor body. The method may further include forming an interlayer dielectric structure on the trench structure. The interlayer dielectric structure may include at least one of an aluminum nitride layer, a silicon nitride layer, an aluminum oxide layer, or a boron nitride layer. The method may further include, after forming the interlayer dielectric structure, forming a source or emitter electrode on the interlayer dielectric structure.

For example, forming the at least one of the aluminum nitride layer, the silicon nitride layer, the aluminum oxide layer, or the boron nitride layer may include forming a first sub-layer by a first process and forming a second sub-layer on the first sub-layer by a second process, the second sub-layer having a larger thickness than the first sub-layer. This may allow for improving sidewall coverages by the sub-layers for ensuring target thickness and improving thermal capacity of the interlayer dielectric structure.

For example, the first process may be an atomic layer deposition process, ALD process, and the second process may be a physical vapor deposition process, PVD process, or a chemical vapor deposition process, CVD process, or a combination of a PVD process and a CVD process.

For example, forming the interlayer dielectric structure may further include forming a first dielectric layer on the trench structure. The at least one of the aluminum nitride layer, the silicon nitride layer, the aluminum oxide layer, or the boron nitride layer or a combination of these materials be formed on the first dielectric layer. For example, the first dielectric layer may be an oxide layer or a nitride layer. Optionally, a third dielectric layer such as an oxide layer may be deposited on the at least one of the aluminum nitride layer, the silicon nitride layer, the aluminum oxide layer, or the boron nitride layer.

The examples and features described above and below may be combined.

More details and aspects are mentioned in connection with the examples described above or

below. Processing a semiconductor body, e.g. a wafer, may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

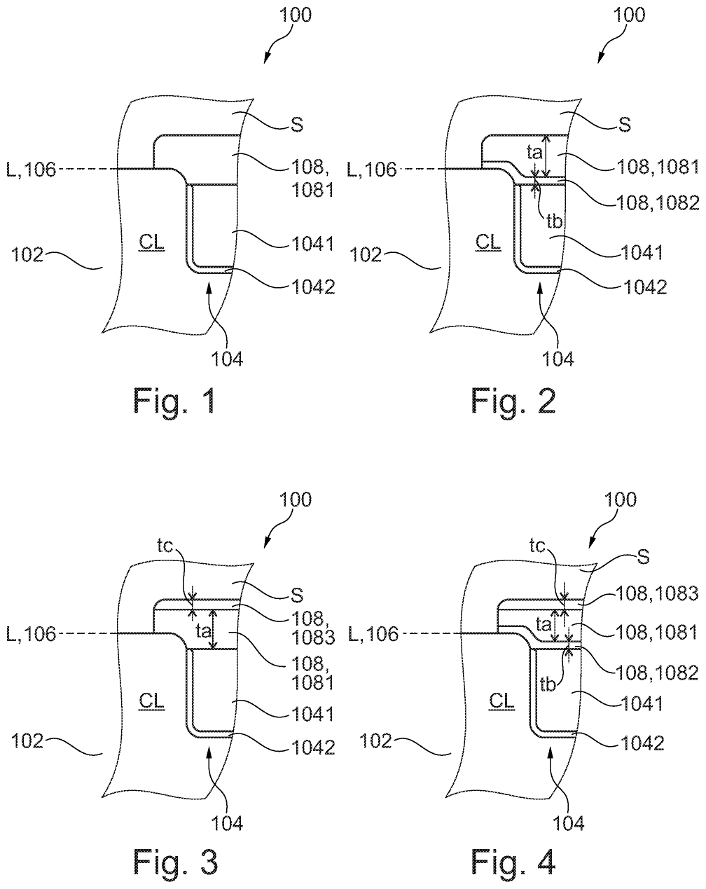

FIG. 1 schematically and exemplarily shows a partial cross-sectional view of a vertical power semiconductor device 100.

The vertical power semiconductor device includes a SiC semiconductor body 102. A trench structure 104 extends into the SiC semiconductor body 102 from a reference level L at a first surface 106 of the SiC semiconductor body 102.

The trench structure 104 includes a gate electrode 1041 and a gate dielectric 1042. The gate dielectric 1042 is arranged between the gate electrode 1041 and the SiC semiconductor body 102. An interlayer dielectric structure 108 is arranged on the trench structure 104. The interlayer dielectric structure 108 includes an aluminum nitride, AlN, layer 1081. In addition to the aluminum nitride layer 1081 or as an alternative to the aluminum nitride layer 1081, a silicon nitride layer, an aluminum oxide layer, or a boron nitride layer, or any combination thereof, may be used. In the example illustrated in FIG. 1, the aluminum nitride layer 1081 adjoins to each of the gate electrode 1041, the gate dielectric 1042 and the first surface 106 of the SiC semiconductor layer 102.

A source or emitter electrode S is arranged on the interlayer dielectric structure 108. The source or emitter electrode S is electrically connected to the SiC semiconductor body 102 at the first surface 106. A bottom side of the source or emitter electrodes adjoins to a top side of the interlayer dielectric structure 108.

The specific structure of doped semiconductor regions, e.g. source or emitter region(s), body and/or body contact region(s), current spread region(s), diode region(s), drift region(s) or zone(s), in the SiC semiconductor body 102 depend on the type of vertical power semiconductor device, e.g. JFET, or MOSFET, or IGBT, and also depend on the specific layout chosen for the device cells. The schematic illustration in FIG. 1 (and likewise FIGS. 2, 3, 4 below) may include any of specific trench device cell layouts and is simplified by summarizing the variety of these layouts by reference symbol CL.

FIG. 2 schematically and exemplarily shows a partial cross-sectional view of another configuration example of a vertical power semiconductor device 100.

The vertical power semiconductor device 100 illustrated in FIG. 2 differs from the exemplary vertical power semiconductor device 100 illustrated in FIG. 1 in that it further includes a first dielectric layer 1082 between the of the aluminum nitride layer 1081 and the trench structure 104. For example, the first dielectric layer 1082 may be an oxide layer or a nitride layer.

A ratio of a thickness ta of the aluminum nitride layer 1081 to a thickness tb of the first dielectric layer 1082 may range from 2 to 200, for example.

FIG. 3 schematically and exemplarily shows a partial cross-sectional view of another configuration example of a vertical power semiconductor device 100.

The vertical power semiconductor device 100 illustrated in FIG. 3 differs from the exemplary vertical power semiconductor device 100 illustrated in FIG. 1 in that it further includes a second dielectric layer 1083 between the source or emitter electrode S and the aluminum nitride layer 1081. For example, the second dielectric layer 1083 may be an oxide layer or a nitride layer.

A ratio of a thickness ta of the aluminum nitride layer 1081 to a thickness tc of the second dielectric layer 1083 may range from 2 to 100, for example.

FIG. 4 schematically and exemplarily shows a partial cross-sectional view of another configuration example of a vertical power semiconductor device 100 that includes a combination of the first dielectric layer 1082, the second dielectric layer 1083 and the AlN layer 1081.

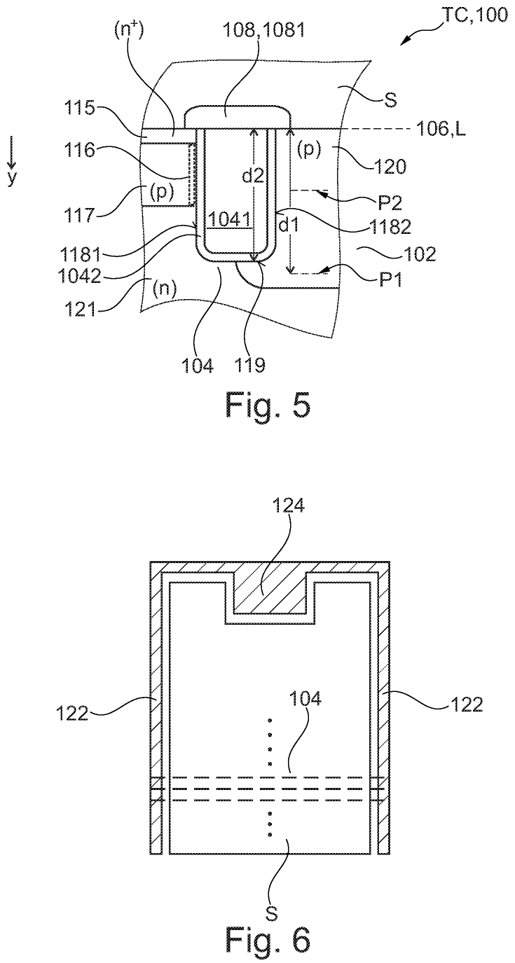

The schematic cross-sectional view of FIG. 5 illustrates a configuration example of a trench device cell TC of a vertical power semiconductor device 100. The trench structure 104 extends into the SiC semiconductor body 102 from the reference level L at the first surface 106 of the SiC semiconductor body 102. An n⁺-doped source region 115 is formed at the first surface 106 of the SiC semiconductor body 102. A channel region 116 adjoins to a first sidewall 1181 of the trench structure 102. The channel region 116 is part of a p-doped body region 117. An n-doped drift zone 121 is arranged below the p-doped body region 117. A conductivity change in the channel region 116 may be controlled by field-effect via a change of the voltage applied to the gate electrode 1041. The trench device cell TC further includes a p-doped diode region 120 adjoining to a second sidewall 1182 and to a bottom side 119 of the trench structure 104. The second sidewall 1182 is opposite to the first sidewall 1181.

The diode region 120 includes two sub-regions 1201, 1202 along a vertical direction y. A vertical doping concentration profile of each of the two sub-regions includes a doping concentration peak P1, P2. A vertical position of the doping concentration peaks P1, P2 is indicated by a dashed line in FIG. 5. The two sub-regions 1201, 1202 may be formed by at least two ion implantation processes using a common ion implantation mask over the first surface 106 of the SiC semiconductor body 102. In the configuration example of FIG. 5, the doping concentration peak P1 is located at a larger vertical distance d1 to a reference level L at the first surface 106 of the SiC semiconductor body 102 than a bottom side 119 of the trench structure 104 having a vertical distance d2. The number of doping concentration peaks illustrated in FIG. 5 is only exemplary and may vary. Depending on the thermal budget and diffusion behavior of dopants forming the diode region 120, doping concentration peaks may also not be present. This may be caused by a vertical diffusion of dopants leading to a widening of the as-implanted dopant concentration profiles.

FIG. 6 schematically and exemplarily shows a top view of a vertical power semiconductor device 100. The source or emitter electrode S includes a source or emitter pad configured to act as a wire bonding surface, for example. The source or emitter electrode S is partly surrounded by a gate runner line 122 that merges with a gate pad 124. Transistor cells including the trench structures 104 comprising the interlayer dielectric structure as described in any of the examples herein are schematically illustrated in FIG. 6 as stripes extending in parallel to each other. The gate electrode in the trench structures 104 is electrically connected to the gate pad 124 via the gate runner.

The description and drawings merely illustrate the principles of the disclosure. Furthermore, all examples recited herein are principally intended expressly to be only for illustrative purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

The aspects and features mentioned and described together with one or more of the previously detailed examples and figures, may as well be combined with one or more of the other examples in order to replace a like feature of the other example or in order to additionally introduce the feature to the other example.

What is claimed is:

1. A vertical power semiconductor device, comprising:
a silicon carbide (SiC) semiconductor body including a trench structure extending into the SiC semiconductor body at a first surface of the SiC semiconductor body, wherein the trench structure includes a gate electrode and a gate dielectric arranged between the gate electrode and the SiC semiconductor body;
an interlayer dielectric structure on the trench structure, wherein the interlayer dielectric structure includes at least one of an aluminum nitride layer, a silicon nitride layer, an aluminum oxide layer, or a boron nitride layer; and
a source or emitter electrode on the interlayer dielectric structure.

2. The vertical power semiconductor device of claim 1, wherein the interlayer dielectric structure is predominantly formed by or consists of the at least one of the aluminum nitride layer, the silicon nitride layer, the aluminum oxide layer, or the boron nitride layer.

3. The vertical power semiconductor device of claim 1, wherein a bottom side of the interlayer dielectric structure directly adjoins to each of the first surface of the SiC semiconductor body, the gate dielectric, and the gate electrode.

4. The vertical power semiconductor device of claim 3, wherein a top side of the interlayer dielectric structure directly adjoins to the source or emitter electrode.

5. The vertical power semiconductor device of claim 1, wherein the at least one of the aluminum nitride layer, the silicon nitride layer, the aluminum oxide layer, or the boron nitride layer directly adjoins to the gate dielectric.

6. The vertical power semiconductor device of claim 1, wherein the interlayer dielectric structure further includes a dielectric layer between the trench structure and the at least one of the aluminum nitride layer, the silicon nitride layer, the aluminum oxide layer, or the boron nitride layer.

7. The vertical power semiconductor device of claim 6, wherein the dielectric layer is an oxide layer or a nitride layer.

8. The vertical power semiconductor device of claim 6, wherein a ratio of a thickness of the at least one of the aluminum nitride layer, the silicon nitride layer, the aluminum oxide layer, or the boron nitride layer to a thickness of the dielectric layer ranges from 2 to 200.

9. The vertical power semiconductor device of claim 1, wherein the interlayer dielectric structure further includes a dielectric layer between the source or emitter electrode and the at least one of the aluminum nitride layer, the silicon nitride layer, the aluminum oxide layer, or the boron nitride layer.

10. The vertical power semiconductor device of claim 9, wherein the dielectric layer is an oxide layer or a nitride layer.

11. The vertical power semiconductor device of claim 9, wherein a ratio of a thickness of the at least one of the aluminum nitride layer, the silicon nitride layer, the aluminum oxide layer, or the boron nitride layer to a thickness of the dielectric layer ranges from 2 to 100.

12. The vertical power semiconductor device of claim 1, wherein a thickness of the at least one of the aluminum nitride layer, the silicon nitride layer, the aluminum oxide layer, or the boron nitride layer ranges from 200 nm to 5 μm.

13. The vertical power semiconductor device of claim 1, further comprising:
a channel region adjoining to a first sidewall of the trench structure; and
a diode region adjoining to a second sidewall and to a bottom side of the trench structure, the second sidewall being opposite to the first sidewall.

14. The vertical power semiconductor device of claim 1, further comprising:
a drain or collector electrode over a second surface of the SiC semiconductor body; and
a drift zone in the SiC semiconductor body between the source or emitter electrode and the drain or collector electrode,
wherein a doping concentration profile of the drift zone is configured for a nominal blocking voltage between the drain or collector electrode and the source or emitter electrode in a range from 300 V to 20 kV.

15. A method of manufacturing a vertical power semiconductor device, the method comprising:
forming a trench structure in a silicon carbide (SiC) semiconductor body at a first surface of the SiC semiconductor body, wherein the trench structure includes a gate electrode and a gate dielectric arranged between the gate electrode and the SiC semiconductor body;
forming an interlayer dielectric structure on the trench structure, wherein the interlayer dielectric structure includes at least one of an aluminum nitride layer, a silicon nitride layer, an aluminum oxide layer, or a boron nitride layer; and
forming a source or emitter electrode on the interlayer dielectric structure.

16. The method of claim 15, wherein forming the at least one of the aluminum nitride layer, the silicon nitride layer, the aluminum oxide layer, or the boron nitride layer comprises:
forming a first sub-layer by a first process; and
forming a second sub-layer on the first sub-layer by a second process, the second sub-layer having a larger thickness than the first sub-layer.

17. The method of claim 16, wherein the first process is an atomic layer deposition (ALD) process and the second process is a physical vapor deposition (PVD) process or a chemical vapor deposition (CVD) process or a combination of a PVD process and a CVD process.

18. The method of claim 15, wherein forming the interlayer dielectric structure comprises:
forming a first dielectric layer on the trench structure; and
forming the at least one of the aluminum nitride layer, the silicon nitride layer, the aluminum oxide layer, or the boron nitride layer on the first dielectric layer.
